(19) United States
(12) Patent Application Publication
(10) Pub. No.: US 2001/0003026 A1
(43) Pub. Date: Jun. 7, 2001

(54) METHOD OF MANUFACTURING A STRONG PHASE SHIFTING MASK

(76) Inventors: CHIN-LUNG LIN, KAOHSIUNG (TW); YAO-CHING KU, HSIEN (TW)

Correspondence Address: J.C. PATENTS, INC., 1340 REYNOLDS AVENUE, SUITE 114, IRVINE, CA, 92614, US

(21) Appl. No.: 09/276,621

(22) Filed: Mar. 25, 1999

(51) Int. Cl. G03F 9/00; G03C 5/00

(52) U.S. Cl. 430/5; 430/322; 430/323

(57) ABSTRACT

A method of manufacturing a strong PSM. A phase shifting layer is formed on a mask substrate, and a first opening and a second opening are formed within the phase shifting layer by patterning to expose a portion of the mask substrate. Thereafter, the mask substrate is etched along the first opening to a first depth wherein the first depth has a phase shift of 90° with the second opening. The mask substrate is etched again along the first opening to a second depth wherein the second depth has a phase shift of 180° with the second opening. An etching step is then carried out along the first opening and the second opening to obtain simultaneously a third depth and a fourth depth of the first opening and the second opening, respectively, with a phase shift of 180°.

### BACKGROUND OF THE INVENTION

1. Field of the Invention

The invention relates to a method of manufacturing a strong phase shifting mask (PSM), and more particularly to a method of manufacturing a strong PSM with dual trenches.

2. Description of the Related Art

Currently, photolithography plays an essential role in semiconductor fabrication. For example, processes for patterning a structure or doping a region in a wafer always require several photolithography processes. In a photolithography process, exposure resolution and depth of focus (DOF) are two important parameters that determine photolithography quality. As the integration of semiconductor devices increases, a high pattern exposure resolution becomes critical. One proposed solution to obtaining a high pattern exposure resolution would use a light source with a shorter wavelength, such as a deep ultraviolet light with a wavelength of 2480 angstroms produced by a Kr laser. However, even through a light source with shorter wavelength can increase the pattern exposure resolution, the DOF deteriorates. Another recently proposed solution would use a phase shifting mask in photolithography technology so as to obtain a high pattern resolution.

The theory of a PSM is to use a phase shifting layer formed on a conventional photo-mask. The phase shifting layer has a light inversion property that inverts the phase of light passing through the phase shifting layer. When the PSM is exposed to a light source, the light passing through the phase shifting layer has an inverted wave phase and can interfere with a normal light, that has not passed through the phase shifting layer. Since the amplitude of the inverted wave phase is negative, an amplitude subtraction occurs around the interface between the normal light and the inverted wave light, resulting in a zero amplitude. When a wafer is exposed by light that has passed through the PSM, a light intensity distribution, which is the square of the amplitude distribution, with better resolution appears on the wafer. The light intensity distribution actually forms a desired pattern with a better pattern resolution. Using the PSM to obtain a better pattern resolution does not require a new light source with a short wavelength. This is the advantage of the PSM.

Types of PSM include a strong PSM and a weak PSM. The strong PSM further includes a Levenson and an alternating PSM. The weak PSM comprises a half-tone PSM, a rim PSM and an attenuated PSM.

FIG. 1 is a flow chart of steps in the manufacturing process for a strong PSM as known in prior art and FIGS. 2A-2F illustrate the manufacture of a strong PSM corresponding to FIG. 1. Referring to FIG. 1 and FIG. 2A, a chromium film 202 is formed on a quartz substrate 200, and then a photoresist layer 204 is coated on the chromium film 202 (step 100). After the photoresist layer 204 is exposed and developed (step 102), the pattern of the photoresist later 204a is formed and is illustrated as photoresist layer 204a in FIG. 2B. The exposed chromium film 202a is etched to form openings 206, 208 as shown in FIG. 2C (step 106). The photoresist layer 204a is then removed, and accordingly the quartz substrate 200 that is covered with the chromium film 202a is opaque.

Referring to FIG. 1 and FIG. 2D, a photoresist layer 210 is coated again on the quartz substrate 200 (step 108). The opening 208 (FIG. 2C) is covered with the photoresist layer 210 after exposure and development (step 110), so that the opening 206 is exposed. An etching process is then performed on the quartz substrate 200, and the opening 206 exposed by the photoresist layer 210 and the chromium film 202a is etched to a depth ‘d’ to obtain an opening 206a, as shown in FIG. 2E. Then, the photoresist layer 208 is stripped away, as shown in FIG. 2F (step 114).

In order to enhance diffraction of a conventional photo-mask, a phase shift of 180° between the opening 206a and the opening 208 is required. However, in the fabrication of the strong PSM, particles are produced and fall into the opening 206a while etching the quartz substrate 200. Therefore, protuberances are formed on the exposed quartz substrate 200 in the opening 206a and cause a phase defect when light passes through the opening 206a. To prevent the phase defect, the phase shift to 180° is accomplished by etching the quartz substrate 200 three times. The first etching step (step 112) etches the quartz substrate 200 of the opening 206 to a depth ‘d’ with a phase shift of 60°, as shown in FIG. 2F. Thereafter, the steps from FIG. 2D to FIG. 2F (step 108 to step 114) twice repeat etching to a depth ‘d′’, as shown in FIG. 2G, and as a result, a phase shift of 180° between the opening 206b and opening 208 can be attained when light passes through. Since the phase shift to 180° is accomplished by three etching steps, each etching step enables the particles produced by etching the quartz substrate 200 in the opening 206b to reduce in size. Therefore, the phase defect is reduced to 60°. But processes to manufacture the quartz substrate 200 with the opening 206b need at least three steps of photolithography, exposure, development and etching, which not only increases the manufacturing cost, but also spends plenty of cycle time, so that the requirement of economic efficiency for semiconductor device cannot be satisfied.

In addition, when the opening 206b is opened by etching, the exposed quartz substrate 200 within the opening 206b is rough, resulting in scattering as the light passes through. This causes an intensity imbalance between the opening 206b and the opening 208, as shown in FIG. 3. When the photo-mask is utilized to perform photolithography on a semiconductor substrate, a photoresist layer used for the photolithography becomes asymmetrical, leading to an error in the size of the semiconductor device.

### SUMMARY OF THE INVENTION

Therefore, this invention is directed towards a method of manufacturing a strong PSM that reduces the manufacturing cost and cycle time, and also enhances intensity imbalance. A phase shifting layer is formed on a mask substrate, and a first opening and a second opening are formed within the phase shifting layer by patterning to expose a portion of the mask substrate. Thereafter, the mask substrate is etched along the first opening to a first depth wherein the first depth has a phase shift of 90° with the second opening. The mask substrate is etched again along the first opening to a second depth wherein the second depth has a phase shift of 180° with the second opening. An etching step is then carried out along the first opening and the second opening, simultaneously, to obtain respectively a third depth and a fourth depth of the first opening and the second opening with a phase shift of 180°.

This invention uses a 90° phase shift to determine an etching depth of the mask substrate; therefore, photolithography is performed twice and the phase shift of 180° is obtained. Accordingly, the complicated processes as seen in conventional technology can be simplified. Additionally, a dual trenche structure is formed in the mask substrate by an additional etching step after the phase shift reaches 180°. The imbalance intensity is thus improved and the 90° phase defect becomes smaller due to the additional etching step.

It is to be understood that both the foregoing general description and the following detailed description are exemplary and explanatory only and are not restrictive of the invention, as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is flow chart illustrating steps in the manufacturing process of the conventional strong PSM;

FIGS. 2A-2G are schematic, cross-sectional views illustrating manufacture of strong PSM known in prior art;

FIG. 3 shows the intensity distribution of the conventional strong PSM;

FIGS. 4A-4H are schematic, cross-sectional views illustrating manufacture of a strong PSM in a preferred embodiment according to the invention;

FIG. 5 shows the intensity distribution of the strong PSM in a preferred embodiment according to the invention;

FIG. 6 shows a pattern in which a gate is connected with a wiring line; and

FIGS. 7A-7B shows a double exposure photolithography process.

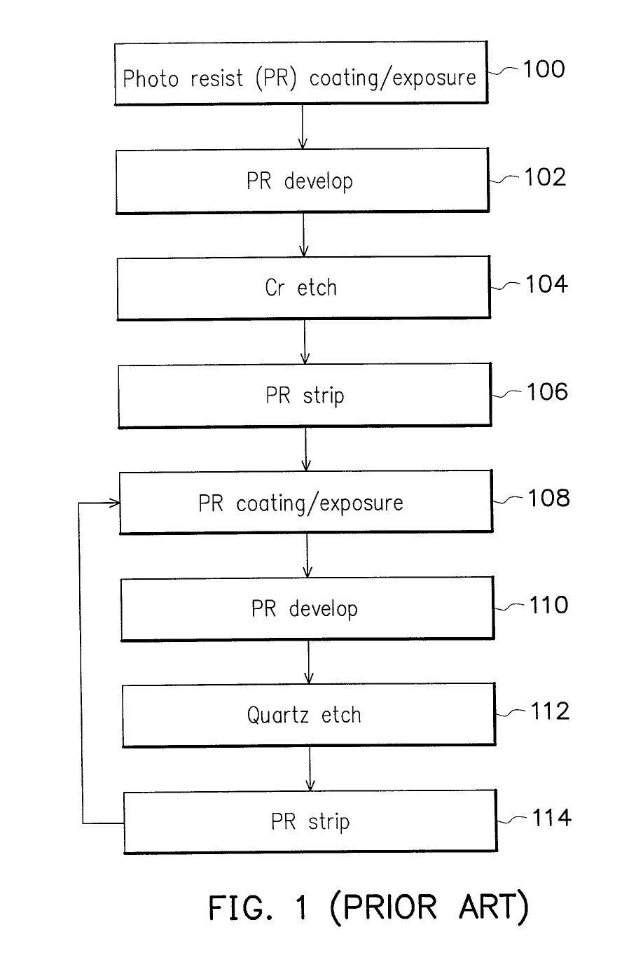

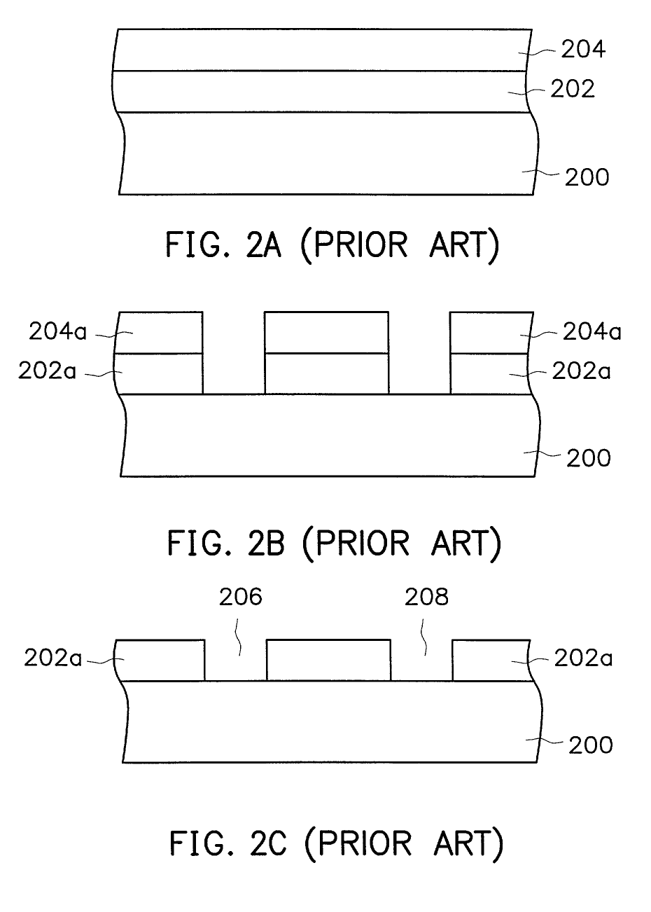

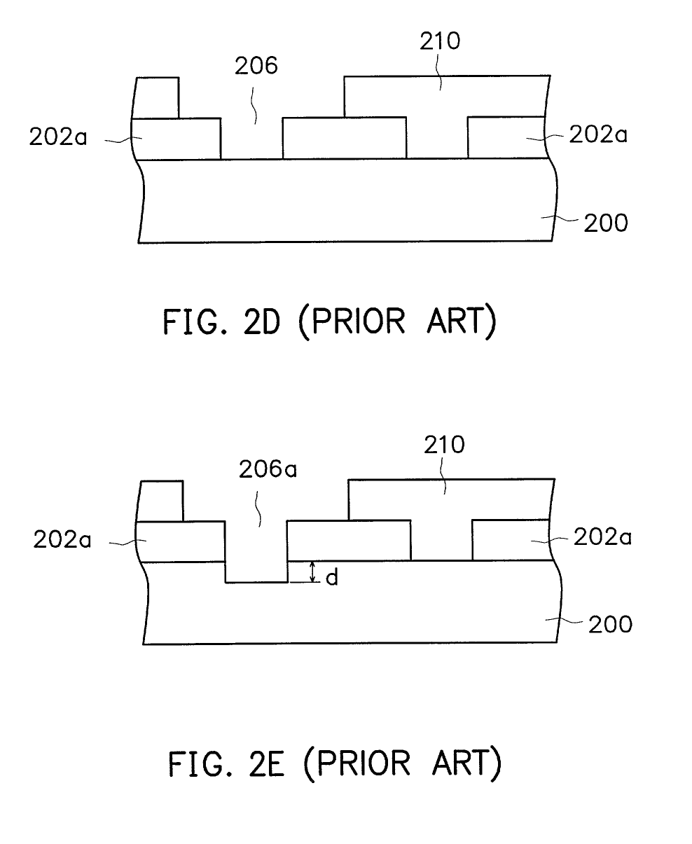

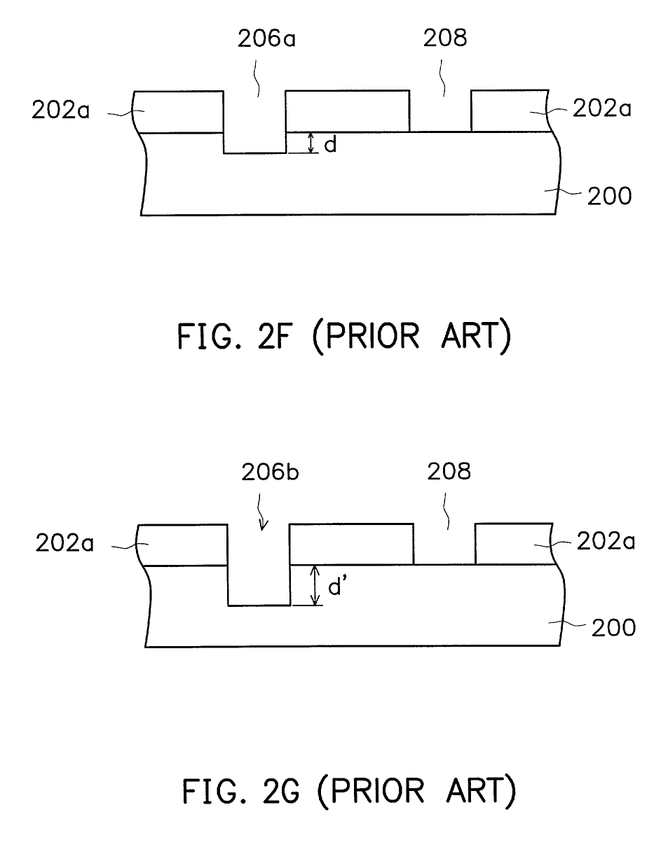

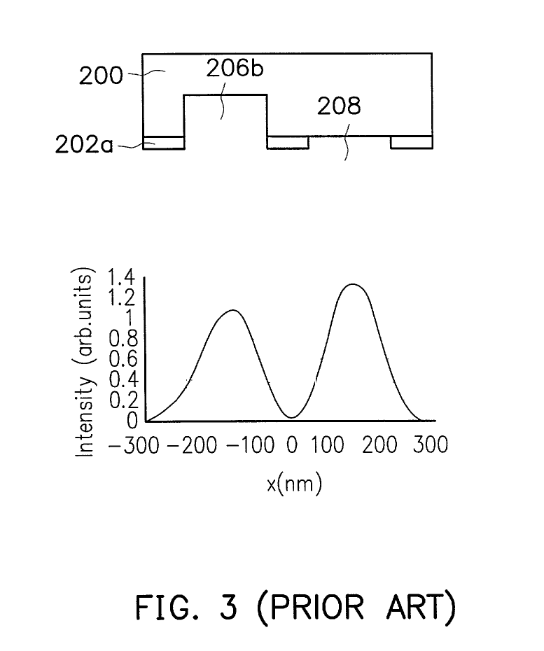

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Two photolithography processes and three etching steps are utilized to reach the required 180° phase shift. There are fewer photolithography processes in the invention than in the prior art. The two openings become dual trench structures after the last etching step to enable equal light intensity when light passes through the dual trenches, and moreover, the phase defect becomes smaller due to the last etching step.

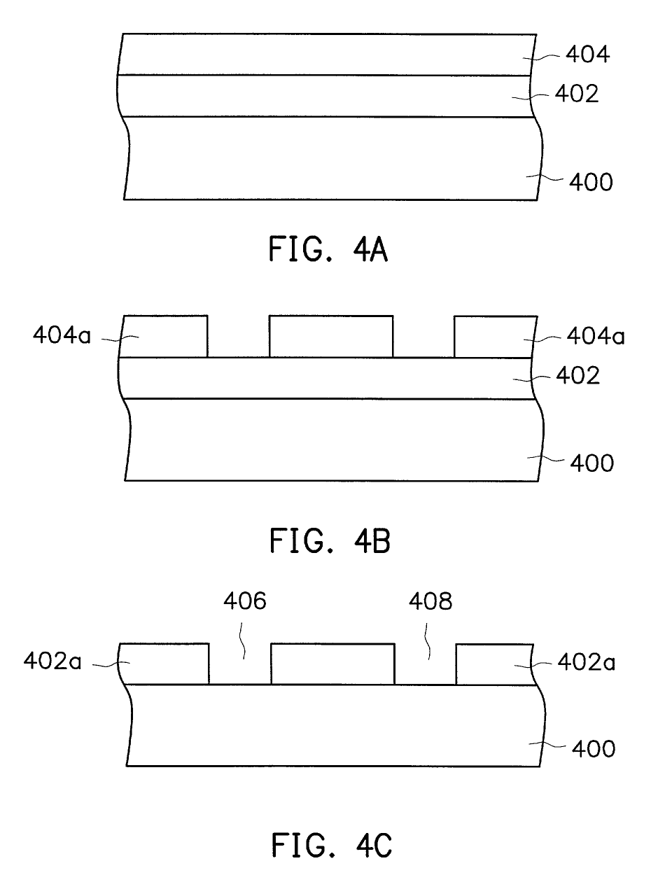

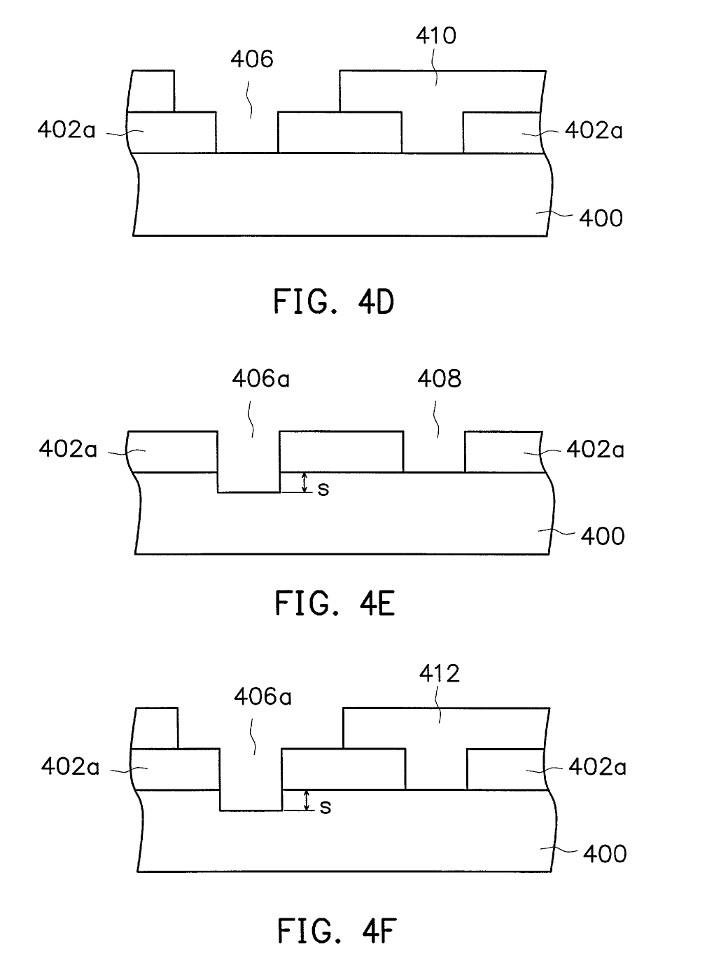

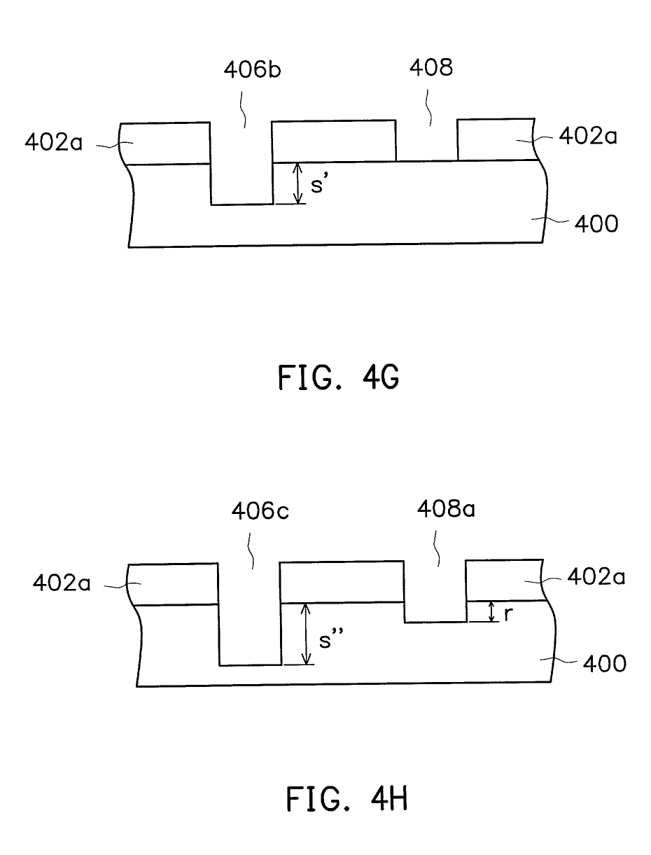

FIGS. 4A-4H are cross-sectional views illustrating manufacture of a strong PSM in a preferred embodiment according to this invention. Referring to FIG. 4A, a phase shifting layer 402 is formed on a mask substrate 400. The mask substrate 400 can be quartz and the phase shifting layer can be chromium. A photoresist layer 404 to define the phase shifting layer 402 is then coated thereon, and the photoresist layer 404a, as shown in FIG. 4B, is formed by exposure and development. The phase shifting layer 402 is then patterned by the photoresist layer 404a. For example, the phase shifting layer 402 exposed by the photoresist layer 404a is removed by wet etching, and openings 406, 408 are formed within the phase shifting layer 402a to expose a portion of the mask substrate 400. The top view of the pattern of the openings 406, 408 depends on the layout design of the semiconductor device.

A photoresist layer 410 is formed and then patterned over the phase shifting layer 402a, as shown in FIG. 4D. The opening 408 is covered with the photoresist layer 410 and the mask substrate 400 of the opening 406 is exposed. With the covering of the photoresist layer 410, an etching step such as dry etching is anisotropically performed on the exposed mask substrate 400 of the opening 406. Referring to FIG. 4E, the mask substrate 400 is etched to a depth ‘s’ to form an opening 406a and then the photoresist layer 410 is stripped. The depth ‘s’ of the opening 406a has a 90° phase shift with the opening 408 when light passes through.

Referring to FIG. 4F, a photoresist layer 412 is coated on the phase shifting layer 402a. After exposure and development, the photoresist layer 412 covers the opening 408 and the mask substrate 400 of the opening 406a is exposed. Then, the exposed mask substrate 400 of the opening 406a is etched to a depth ‘s′’ and when light passes through, a 180° phase shift is produced between the opening 406b and the opening 408, as illustrated in FIG. 4G. The photoresist layer 412 in FIG. 4F is removed.

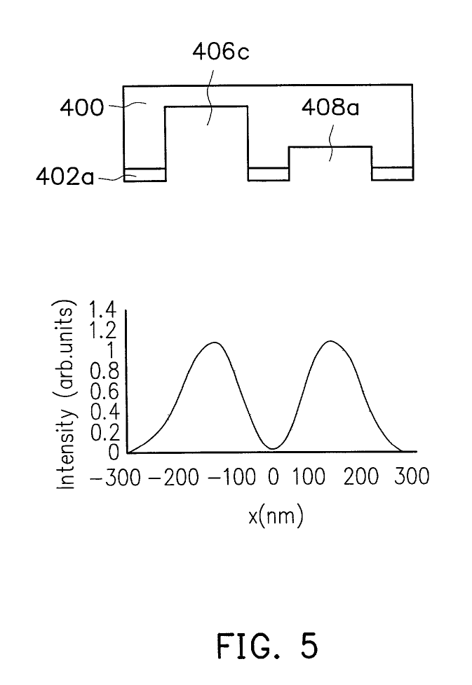

Referring to FIG. 4H, an etching step, such as dry etching, is anisotropically performed on the mask substrate 400. The openings 406b, 408 are thus etched to a depth ‘s″’ and r, respectively, to form a dual trench structure within the mask substrate 400. When light passes through the openings 406c, 408a, the phase shift is maintained at 180°. Since the exposed surface of openings 406c, 408a is obtained by etching steps, they both are rough, and, as a result, scattering from the opening 406c is similar to that of the opening 408a, leading to a balance of the intensity distribution when light penetrates the openings 406c, 408a, as shown in FIG. 5. Because this etching step does not need a photoresist layer on which to form, the particles are not produced from the photoresist layer and left in the openings 406b, 408 to cause a serious phase defect. Additionally, a phase shift of 90° may be generated due to the 90° phase shift etching, but the last etching step is capable etching the particles left in the openings 406b and the phase defect can be reduced. Therefore, the reliability of the photolithography performed by the phase shift mask produced in this invention can be improved. With respect to manufacture of the mask substrate 400, only two photolithography processes and three etching steps are needed to form a dual trench structure. Therefore, the process to fabricate the phase shifting mask in this invention is easier than that of prior art, and the manufacturing cost and cycle time are reduced.

Double exposure, which utilizes two different masks to perform an exposure step, is currently important in development of a phase shifting mask. One mask is a conventional mask and is also called a binary mask. The other mask is a phase shifting mask. The phase shifting mask produced in this invention is used in double exposure, to thereby overcome the difficulties that the conventional mask cannot solve.

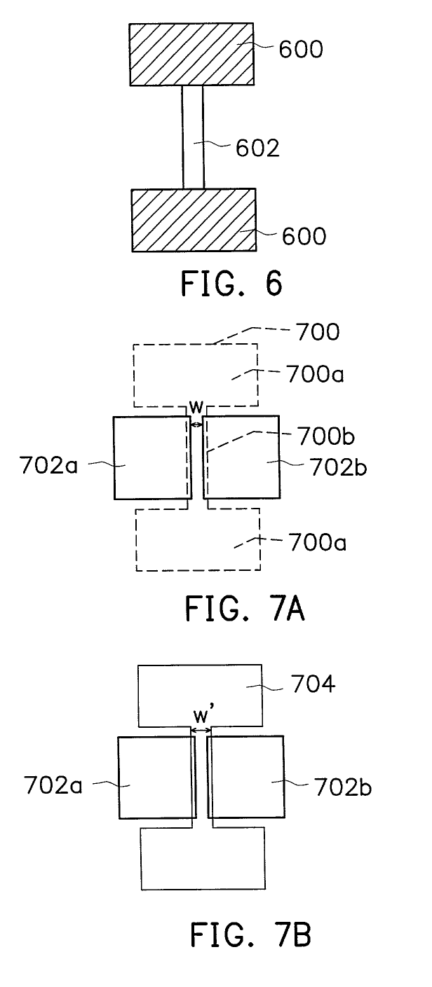

FIG. 6 shows a top view of the layout of semiconductor devices in which the gates 600 are connected with a wiring line 602. In conventional technology, if a binary mask is used to achieve the pattern shown in FIG. 6, the width of the wiring line 602 is restricted with the light source resolution and a desired size that, as it reduces, cannot be obtained. On the other hand, it is more difficult to manufacture a phase shifting mask whose pattern including the gates 600 and the wiring line 602 as is shown in FIG. 6. Accordingly, double exposure is therefore developed.

Referring to FIG. 7A, the dot pattern 700 represents the gates 600 connected with the wiring line 602 in FIG. 6. The first exposure step uses the phase shifting mask manufactured according to this invention. The transparent portion 702a, 702b of the phase shifting mask is disposed beside the wiring line 700b and the opaque portion covers another part of the semiconductor substrate (not shown). The transparent portion 702a, 702b of the phase shifting mask has a phase shift 180°, and a distance between the transparent portions 702a, 702b equals the width of the wiring line 602 in FIG. 6. Since the phase shifting mask with this pattern 702a, 702b is easily fabricated, the manufacturing cost is reduced. Thereafter, the second exposure step utilizes a binary mask. An opaque pattern portion 704 of the binary mask is the same as the gates 600 and the wiring line 602 in FIG. 7B. The only difference is that a width w′ of the opaque portion 704 is larger than the width of the wiring line 602 (FIG. 6). Since the width of the wiring line 602 has been patterned during the first exposure step, the width w′ of pattern 704 is not limited by the width of the wiring line 602. Therefore, the width w′ of the pattern 704 is larger than the width w, and the method to produce the binary mask used for the second exposure step is simplified. Accordingly, using double exposure to carry out the photolithography not only enables the manufacture of mask to be easier, but also achieves the requirement of the line width.

In a word, the process to manufacture the phase shifting mask with dual trenches according to this invention is simplified and the intensity imbalance is improved when light passes through. In addition, the phase defect can be reduced by the last etching step and the dual trench structure is produced by the last etching step. Therefore, the manufacturing cost is reduced, the cycle time is shortened and the resolution of the photolithography process is enhanced. Moreover, the difficulty in the line width and the mask manufacture can be overcome by the phase shifting mask used in the double exposure.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

What is claimed is:

1. A method of manufacturing a strong phase shifting mask, comprising:
providing a mask substrate having a phase shifting layer formed thereon;
forming a first opening and a second opening within the phase shifting layer;
forming a first depth through the first opening within the mask substrate having a 90° phase shifting with the second opening;
forming a second depth through the first opening within the mask substrate having a 180° phase shifting with the second opening;
forming a third depth and a fourth depth within the mask substrate through the first opening and the second opening respectively, so that the third depth has a 180° phase shifting with the fourth depth.

2. The method according to claim 1, wherein the mask substrate includes quartz.

3. The method according to claim 1, wherein the phase shifting layer includes chromium.

4. The method according to claim 1, wherein the first opening and the second opening are formed by patterning the phase shifting layer using a photoresist layer.

5. A method of manufacturing a strong phase shifting mask, comprising:
providing a mask substrate having a phase shifting layer formed thereon;
patterning the phase shifting layer to form a first opening and a second opening;
forming a first photoresist layer over the phase shifting layer to cover the second opening;
etching the mask substrate through the first opening to a first depth, so that a 90° phase shift between the first depth and the second opening is obtained while light is passed through;
removing the first photoresist layer;
forming a second photoresist layer over the phase shifting layer to cover the second opening;
etching the mask substrate again through the first opening to a second depth, so that a 180° phase shift between the second depth and the second opening is obtained when light passes through;
removing the second photoresist layer; and
etching the mask substrate through the first and the second openings, simultaneously, to a third depth and a fourth depth respectively, so that a 180° phase shift between the third depth and the fourth depth is obtained when light passes through.

6. The method according to claim 5, wherein the mask substrate includes quartz.

7. The method according to claim 5, wherein the phase shifting layer includes chromium.

8. The method according to claim 5, wherein the phase shifting layer is patterned using a third photoresist layer.

9. The method according to claim 5, wherein the etching step is performed by anisotropic etching.
